(19) United States
(12) Patent Application Publication
(10) Pub. No.: US 2015/0130479 A1
(43) Pub. Date: May 14, 2015

(54) INFORMATION PROCESSING SYSTEM, INFORMATION PROCESSING APPARATUS, AND CABLE

(71) Applicant: FUJITSU LIMITED, Kawasaki-shi (JP)

(72) Inventor: TADAO AMADA, Kawasaki (JP)

(21) Appl. No.: 14/520,451

(22) Filed: Oct. 22, 2014

(30) Foreign Application Priority Data
Nov. 13, 2013 (JP) 2013-235456

(51) Int. Cl. G01R 31/11

(52) U.S. Cl. CPC G01R 31/11
USPC 324/629

(57) ABSTRACT

An information processing system includes a cable and a first information processing apparatus. The cable connects information processing apparatuses to each other. The cable includes one or more first core wires through which information is transmitted, and one or more second core wires having a shape or component associated with preset information. The first information processing apparatus measures a first parameter that is related to the second core wires and changes with the shape or component, and to identify the cable using the measured first parameter.

### CROSS-REFERENCE TO RELATED APPLICATION

This application is based upon and claims the benefit of priority of the prior Japanese Patent Application No. 2013-235456, filed on Nov. 13, 2013, the entire contents of which are incorporated herein by reference.

### FIELD

The embodiments discussed herein are related to a cable for use in communications.

### BACKGROUND

Many cables for use in communications, which are mass-produced goods, are used for various purposes. Characteristics of the cables themselves seldom become an issue. Hence, the actual situation is that detailed lot control of cables is not performed.

Recently, in some cases, to cope with, for example, high speed transmission, the characteristics of communication cables have varied in accordance with lots, and, when cables are laid, sometimes the positions in which the cable lots are laid may be clarified for maintenance.

The following technologies are know as technologies related to a cable-connected information processing system.

In a method related to a first technology, an impedance measuring circuit is coupled to a transmission medium and a receiver in a high-impedance state, and the impedance measuring circuit is enabled through a de-emphasis controller. In this way, the method related to the first technology sets de-emphasis of a transmitter driver coupled to the receiver through the transmission medium. The impedance measuring circuit measures at least one of a line impedance and a line length of the transmission medium, the transmission medium being an unbalanced load. The de-emphasis controller sets gain of the driver based on the measured at least one of the line impedance and the line length.

In a TDR (Time Domain Reflectometry) timing calibrating method related to a second technology, the DUT (Device Under Test) end of an IC socket is grounded, and a propagation delay time 2×τig (i=1, 2) at a round-trip after a test waveform is applied to one end of an i-th (i=1, 2) transmission line from i (i=1, 2) pin-corresponding circuits before the test waveform is totally reflected at the DUT end of the socket at the other end to return is measured. In the TDR timing calibrating method, a delay amount of a skew adjustment variable delay circuit of the i-th (i=1, 2) pin-corresponding circuit is adjusted with the use of the measured data, and timing of the test waveform of each pin-corresponding circuit at the DUT end is calibrated.

A transmission-line evaluation method related to a third technology includes: a first step wherein an evaluation signal, generated by a waveform generator based on waveform data stored on a storage device, is input to one end of a transmission line being an object of evaluation; a second step wherein waveform data on an output signal, output from the other end of the transmission line, is written to a storage device as new waveform data for generating an evaluation signal by the waveform generator; and a third step wherein a characteristic of the transmission line is evaluated by an evaluation device, based on output signals output from the other end of the transmission line generated by repeatedly executing the first and second steps a predetermined number of times.

A fourth technology describes a non-intrusive, fully automated, variable cable and impedance-based, multiplexed cable testing system that uses Time Domain Reflectometry techniques. The system can process more than one cable type, with varying characteristics, at anyone time, during which it confirms and processes both the characteristics of the cable type under test and any discontinuities encountered during its operational life due to impedance variations defined and processed. Furthermore, the system provides an extensive range of Real-Time Diagnostic and Prognostic data together with accurate location and interpretation of any such data and/or discontinuity including, but not limited to, the additional mapping of impedance variations along the length of the cable.

The technologies described in the following documents are known.

Japanese Laid-open Patent Publication No. 2011-199822

Japanese Laid-open Patent Publication No. 2000-9801

Japanese Laid-open Patent Publication No. 2010-256123

Japanese National Publication of International Patent Application No. 2004-529370

### SUMMARY

According to an aspect of the embodiment, an information processing system includes a cable and a first information processing apparatus. The cable connects information processing apparatuses to each other. The cable includes one or more first core wires through which information is transmitted, and one or more second core wires having a shape or component associated with preset information. The first information processing apparatus measures a first parameter that is related to the second core wires and changes with the shape or component, and to identify the cable using the measured first parameter.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an exemplary configuration of an information processing system in accordance with an embodiment;

FIG. 2 illustrates an exemplary configuration of a cable-connected information processing system in accordance with embodiment 1;

FIG. 3 illustrates an exemplary configuration of management information;

FIG. 4 illustrates bending patterns of a lot-management core wire;

FIG. 5 illustrates an exemplary hardware configuration of a first information processing apparatus;

FIG. 6 illustrates an exemplary configuration of a cable-connected information processing system in accordance with embodiment 2;

FIG. 7 illustrates an exemplary configuration of a cable in accordance with embodiment 3;

FIG. 8 illustrates an exemplary configuration of a cable-connected information processing system in accordance with embodiment 3;

FIG. 9 illustrates an exemplary configuration of a cable-connected information processing system in accordance with embodiment 4;

FIG. 10 is a flowchart illustrating processes performed by a processing unit of a ninth information processing apparatus in accordance with embodiment 4; and

FIG. 11 is a flowchart illustrating processes performed by a position information extracting unit of a ninth information processing apparatus in accordance with embodiment 4.

### DESCRIPTION OF EMBODIMENTS

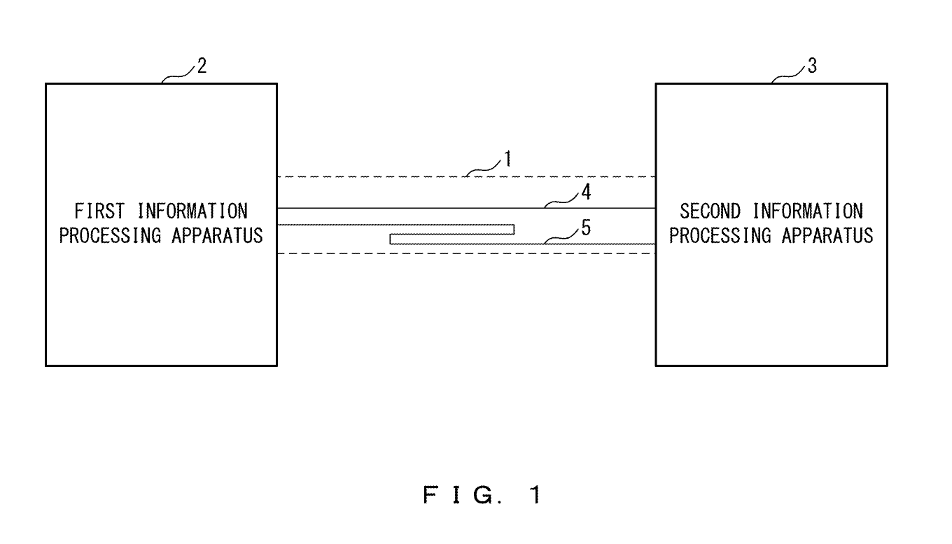

FIG. 1 illustrates an exemplary configuration of an information processing system in accordance with an embodiment. In FIG. 1, the information processing system includes a first information processing apparatus 2 and a second information processing apparatus 3. A cable 1 connects the first information processing apparatus 2 and the second information processing apparatus 3 to each other.

The cable 1 connects the information processing apparatuses. The cable 1 includes one or more first core wires 4 through which information is transmitted, and one or more second core wires 5 having a shape or component associated with preset information. The shape associated with preset information is the length or bending pattern of the second core wire 5. The second core wire 5 is bent backward in a pattern associated with lot information of the cable 1. The cable 1 includes a housing of conductive material connected to the second core wire 5.

The first information processing apparatus 2 measures a first parameter that is related to the second core wire 5 and that changes with the shape or component of the second core wire 5, and identifies the cable using the measured first parameter. The first information processing apparatus 2 measures the first parameter via the housing.

The second information processing apparatus 3 measures a second parameter that is related to the second core wire 5 and that changes with the shape or component of the second core wire 5, and transmits the measured second parameter to the first information processing apparatus 2. Upon receipt of the second parameter, the first information processing apparatus 2 determines whether the first and second parameters are consistent with each other.

The first parameter is an ohmic value, an S parameter, or a measured value based on time domain reflectometry.

Lot information indicates, for example, the part number or date of manufacture of a cable. A plurality of managed cables each have unique lot information allocated thereto.

The cable 1 in accordance with the embodiment enables measurement of a parameter specific to each of the plurality of managed cables, and the parameter is associated with lot information, thereby allowing lot information of the cable to be identified. A core wire of a cable is used to make a measurable parameter specific to the cable. This may minimize a change that needs to be made to cable assembling processes, e.g., a process of incorporating a semiconductor circuit such as a memory into a cable to maintain a specific parameter in the cable.

### Embodiment 1

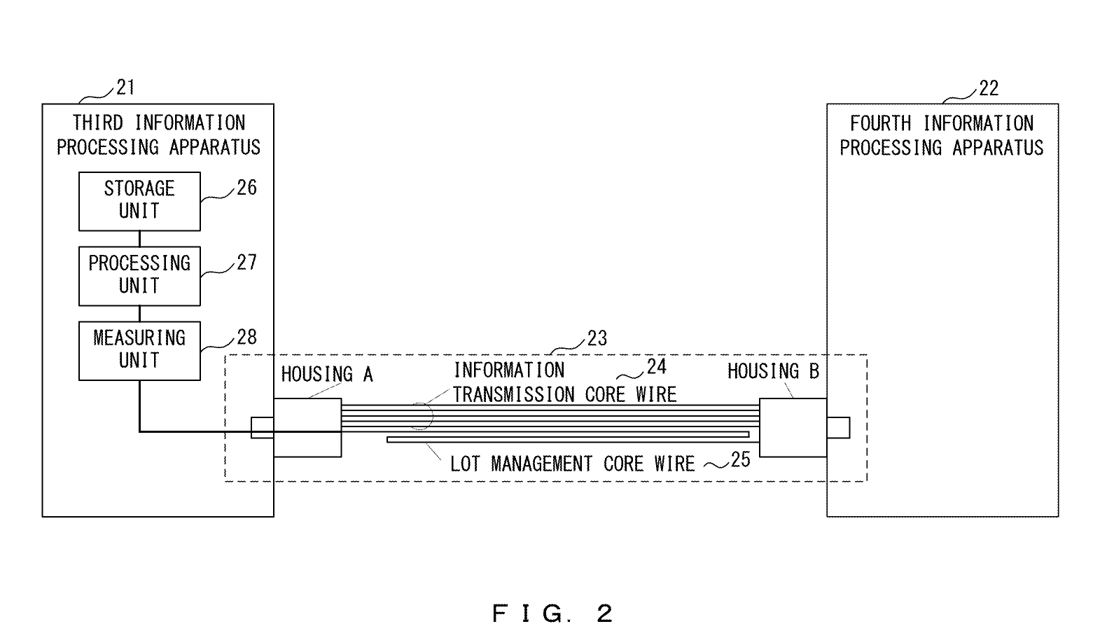

FIG. 2 illustrates an exemplary configuration of a cable-connected information processing system in accordance with embodiment 1. In FIG. 2, the information processing system includes a third information processing apparatus 21 and a fourth information processing apparatus 22. A cable 23 connects the third information processing apparatus 21 and the fourth information processing apparatus 22 to each other.

The third information processing apparatus 21 is an example of the first information processing apparatus 2. The fourth information processing apparatus 22 is an example of the second information processing apparatus 3. The cable 23 is an example of the cable 1.

The cable 23 includes an information transmission core wire 24 and a lot management core wire 25. The information transmission core wire 24 is an example of the first core wire 4. The lot management core wire 25 is an example of the second core wire 5.

The information transmission core wire 24 connects housings A and B provided at the ends of the cable 23. Signals are transmitted through the information transmission core wire 24. The information transmission core wire 24 is used for typical cable applications.

The lot management core wire 25 is used to identify lot information of the cable 23. The lot management core wire 25 is connected in such a manner as to be bent backward at one or more points between the housings A and B within the cable 23. Changing the bending pattern for each of the plurality of managed cables adjusts the lengths of the lot management core wires 25. The bending pattern is changed for each of the plurality of managed cables in such a manner that the lot management core wire 25 of each of the cables has a unique length, with the result that a unique parameter determined in accordance with the length of each of the lot management core wires 25 becomes a unique value for each of the cables. Accordingly, measuring a unique parameter determined in accordance with the length of the lot management core wire 25 enables obtainment of a value specific to each of the plurality of managed cables. Unique parameters determined in accordance with the length of the lot management core wire 25 include, for example, the ohmic value of the lot management core wire 25, a value measured using TDR (Time Domain Reflectometry), and an S parameter value indicating the characteristic of a circuit network. When the parameter to be measured is an S parameter, the lot management core wire 25 may include a plurality of core wires such as twisted pair wires and twinax wires.

In this example, the parameter to be measured is made unique by adjusting the length of the lot management core wire 25, but components (ratio between the amounts of components) of lot management core wires 25 may be adjusted to achieve a unique parameter for each managed cable. In particular, impurities may be added to a conductor included in the lot management core wires 25 so that the impurity content can be adjusted (changed) for each of the plurality of managed cables to make a measured parameter, e.g., an ohmic value, different for each cable.

The fourth information processing apparatus 22 transmits information to and receives information from the third information processing apparatus 21 through the information transmission core wire 24 of the cable 23.

The third information processing apparatus 21 includes a storage unit 26, a processing unit 27, and a measuring unit 28.

The storage unit 26 stores management information. Management information associates lot information of a cable and the value of a parameter with each other. Management information is used to identify lot information associated with a measured parameter of a cable. Management information associates lot information with the value of a parameter, and the value of a parameter is a unique value determined in accordance with the length of the lot management core wire 25. Hence, the length of the lot management core wire 25 of each of the plurality of managed cables is associated with lot information.

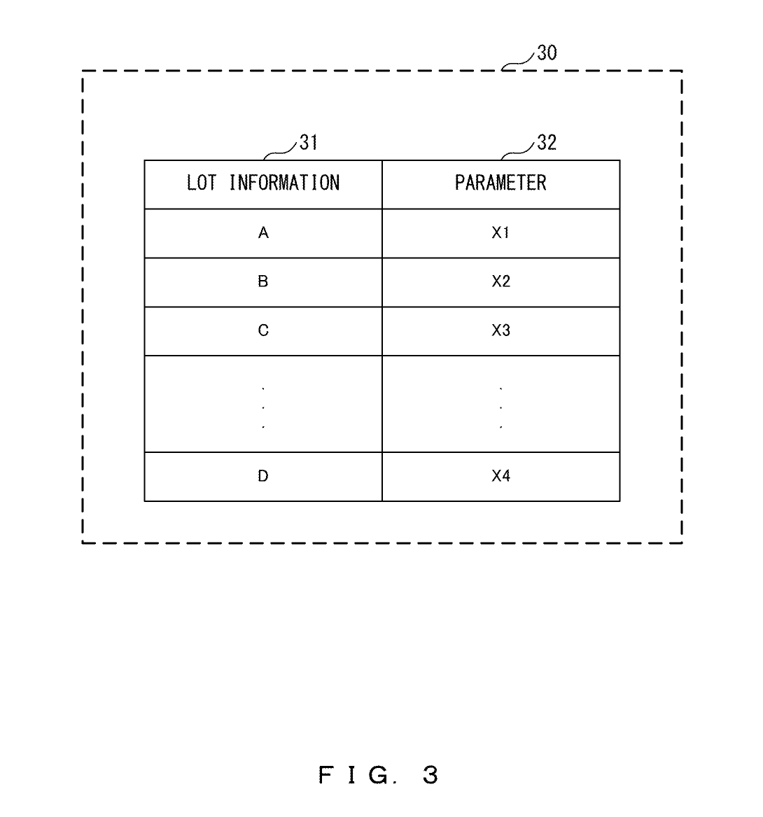

FIG. 3 illustrates an exemplary configuration of management information 30. Management information 30 includes the following data items: lot information 31 and parameter 32. Lot information 31 is unique lot information allocated to each of the plurality of managed cables. The parameter 32 is a unique parameter determined in accordance with the length of the lot management core wire 25 of a cable corresponding to lot information 31. Lot information 31 of a cable and the value of the parameter 32 thereof are stored in each record of management information 30 in advance at the time of shipment of the cable or before the cable is laid.

The unique parameter determined in accordance with the length of the lot management core wire 25 may hereinafter be simply referred to as a parameter.

The processing unit 27 identifies lot information of the cable 23 using the parameter of the lot management core wire 25 and management information 30. In particular, the processing unit 27 first instructs the measuring unit 28 to measure the parameter of the lot management core wire 25 and receives the measured parameter from the measuring unit 28. Then, the processing unit 27 extracts, from management information 30, a record with the parameter 32 indicating a value that is identical with the value of the received parameter, and obtains the value of the lot information 31 of the extracted record. In this way, the processing unit 27 identifies the lot information of the cable 23.

The measuring unit 28 receives from the processing unit 27 an instruction to measure the parameter of the lot management core wire 25 and measures the parameter of the lot management core wire 25. The measuring unit 28 transmits the measured parameter of the lot management core wire 25 to the processing unit 27.

In the descriptions above, the measured parameters are unique parameters determined in accordance with the lengths of core wires, but measured parameters may be unique parameters determined in accordance with bending patterns. Such parameters include, for example, a value measured using TDR. In TDR, fast pulses and step signals are applied to the lot management core wire 25, and the waveform of a returning reflected wave is used to detect a change in characteristic impedance. This allows the detection of the bending pattern of the lot management core wire 25. In one possible example, the TDR-based measurement enables the detection of the number of points at which the lot management core wire 25 is bent backward, and hence such a number can be used as a parameter.

The user may use another apparatus to perform the process of causing the measuring unit 28 to measure the parameter of the lot management core wire 25, and to perform the process of causing the processing unit 27 to identify lot information of the cable 23 using a parameter and management information 30. For example, the parameter of the lot management core wire 25 may be measured using a portable measuring apparatus, and the user may input the measured value to the processing unit 27 to cause the processing unit 27 to identify lot information using the input measured value and management information 30.

A plurality of lot management core wires 25 may be provided. That is, management information 30 may manage unique lot information associated with a combination of the values of the parameters of the plurality of lot management core wires 25.

The following will describe the bending of the lot management core wire 25 backward within the cable 23.

The lot management core wire 25 of each cable is bent backward in a manner such that the lot management core wire 25 of every managed cable has a unique length. However, for a measuring-subject parameter that is a unique parameter determined in accordance with a bending pattern, the lot management core wire 25 of each cable is bent backward in a manner such that every managed cable is associated with a unique bending pattern.

In particular, the lot management core wires 25 of a plurality of managed cables are bent backward in a manner such that every cable has, for example, a unique combination of the positions of points at which the lot management core wire 25 is bent backward and the number of such points. However, a set of combinations is present that have lot management core wires 25 of the same length and that each have a different combination of the positions of points at which the lot management core wire 25 is bent backward and the number of such points. For such a set of combinations, one combination from among the set is used as a bending pattern.

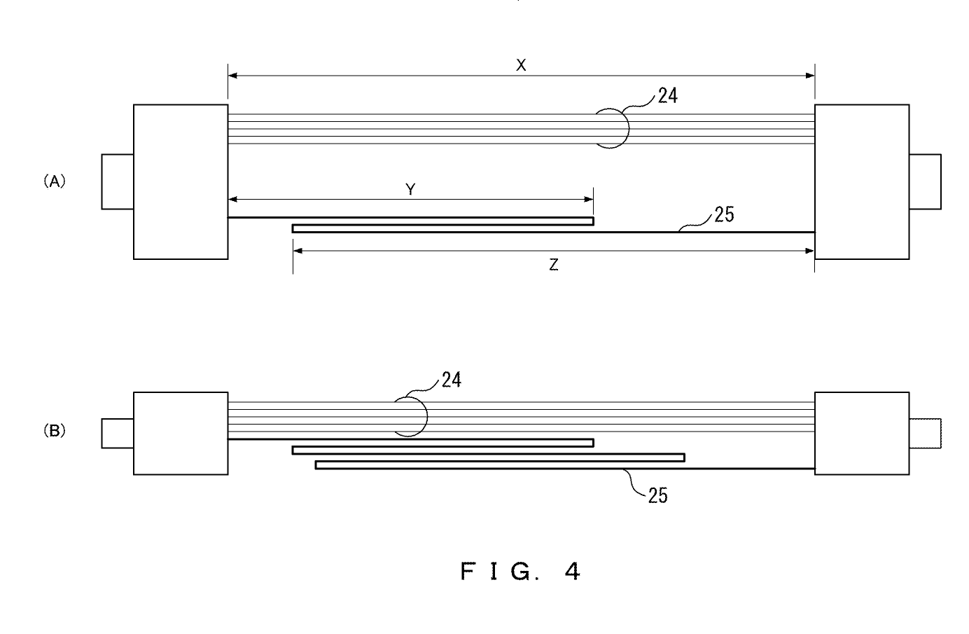

FIGS. 4A and 4B illustrate bending patterns of the lot management core wire 25. Assume that the lot management core wire 25 is bent backward at two points as depicted in FIG. 4A, where X indicates the length of the information transmission core wire 24; Y, the distance from one end of the lot management core wire 25 to a first bending point; and Z, the distance from the other end of the lot management core wire 25 to a second bending point. Accordingly, the lot management core wire 25 of each managed cable is bent backward in a manner such that only one of the managed cables corresponds to a combination (Y, Z) satisfying (Y<X, Z<X) and (X≦Y+Z). However, when the two combinations (Y, Z) and (Y′, Z′), where (Y≠Z), satisfy (Y′=Z, Z′=Y), the core wires have the same length, and, accordingly, one of the combinations is excluded. In one possible example, each cable may be bent backward in such a manner as to add 1 (cm (centimeter)) to Y and Z or subtract 1 (cm (centimeter)) from Y and Z.

FIG. 4B illustrates an exemplary cable wherein the lot management core wire 25 is bent backward at four points. As depicted in FIG. 4B, the lot management core wire 25 may be bent backward at four or more points. Increasing the number of points at which the lot management core wire 25 is bent backward may lead to more bending patterns.

The difference in length of a lot management core wire 25 between cables (difference in bending pattern between cables) may be changed in accordance with the measurement accuracy of a parameter measuring apparatus. That is, in the case of, for example, a measuring apparatus with a low measurement accuracy, a large difference may be made between the length (bending patterns) of a predetermined cable and the length (bending patterns) of another cable. In accordance with the number of managed cables, i.e., the number of pieces of lot information, a change may be made to the difference in length of a lot management core wire 25 between the cables (difference in bending pattern between the cables).

Such a configuration enables the cables to be identified by measuring the parameters thereof even after the cables are laid. Associating the value of the parameter of a cable with the lot information thereof allows the lot information of the cable to be identified after the cable is laid. When, for example, a cable 23 connected to the third information processing apparatus 21 is replaced with another cable, the third information processing apparatus 21 may recognize the replacement of the cable 23 and automatically identify the lot information of that other cable.

Use of a core wire of a cable as a means for identifying lot information allows the cable itself to have information for identification of the lot information without significantly changing cable assembling processes.

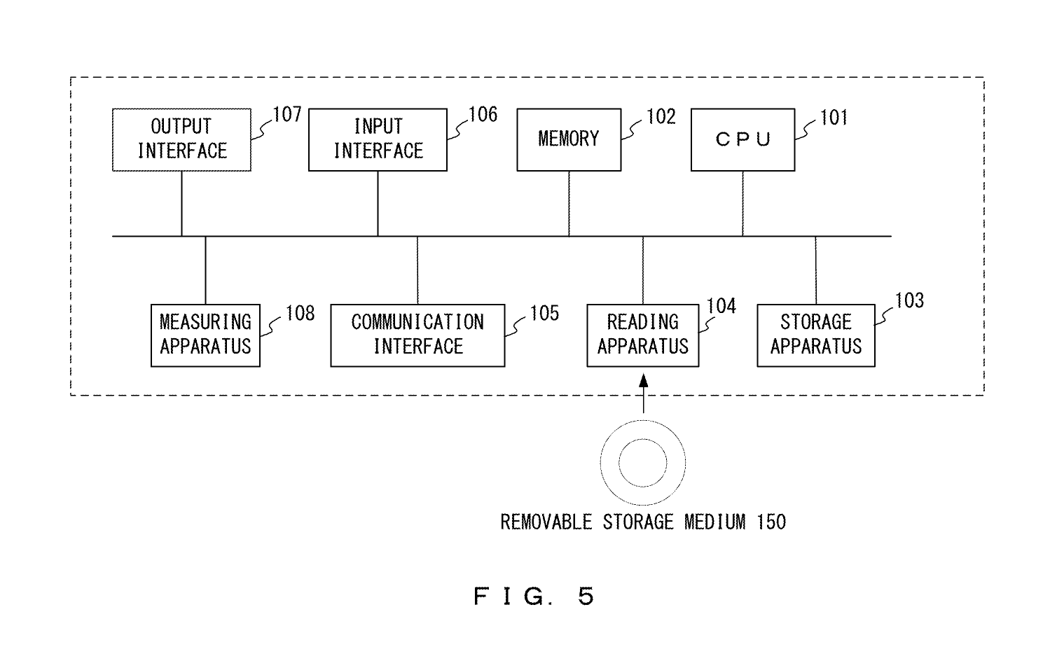

The following will describe the configuration of the third information processing apparatus 21. FIG. 5 illustrates an exemplary hardware configuration of the third information processing apparatus 21.

The third information processing apparatus 21 includes a CPU (Central Processing Unit) 101, a memory 102, a storage apparatus 103, a reading apparatus 104, a communication interface 105, an input interface 106, an output interface 107, and a measuring apparatus 108. The CPU 101, the memory 102, the storage apparatus 103, the reading apparatus 104, the communication interface 105, the input interface 106, the output interface 107, and the measuring apparatus 108 are connected to each other by a bus.

The CPU 101 uses the memory 102 to provide a portion of or the entirety of the function of the processing unit 27.

The memory 102 is, for example, a semiconductor memory and is configured to include a RAM (Random Access Memory) region and a ROM (Read Only Memory) region. The storage apparatus 103 is, for example, a hard disk and stores a program of the embodiment. The storage apparatus 103 may be a semiconductor memory such as a flash memory. The storage apparatus 103 may be an external recording apparatus. The storage apparatus 103 is an example of the storage unit 26.

In accordance with an instruction from the CPU 101, the reading apparatus 104 accesses a removable storage medium 150. The removable storage medium 150 is achieved by, for example, a semiconductor device (e.g., USB memory), a medium to which information is input and from which information is output through a magnetic effect (e.g., magnetic disk), or a medium to which information is input and from which information is output through an optical effect (e.g., CD-ROM, DVD). The third information processing apparatus 21 does not necessarily include the reading apparatus 104.

The communication interface 105 is connected to the fourth information processing apparatus 22 by the cable 23 so as to transmit and receive information. The communication interface 105 may be configured using a circuit.

The input interface 106 is connected to an input apparatus. The third information processing apparatus 21 may not include the input interface 106.

The output interface 107 is connected to an output apparatus. The third information processing apparatus 21 may not include the output interface 107.

The measuring apparatus 108 measures a parameter of the lot management core wire 25 of the cable 23. The measuring apparatus 108 is an example of the measuring unit 28. When, for example, a parameter to be measured is an ohmic value, the measuring apparatus 108 is an ohmic-value measuring circuit. In one possible example, the ohmic-value measuring circuit applies a voltage to the lot management core wire 25, uses an ammeter to measure a current flowing through the lot management core wire 25, and calculates the ohmic value of the lot management core wire 25 from the voltage and the current. In such a case, with reference to, for example, FIG. 2, the end of the lot management core wire 25 connected to the fourth information processing apparatus 22 may be grounded, or may be connected using, for example, a ground line included in the cable 23 in a manner such that a potential difference can be calculated across the ends of the lot management core wire 25. Another example of the ohmic-value measuring circuit is a Wheatstone bridge. When, for example, a parameter to be measured is a value measured using TDR, the measuring apparatus 108 is a TDR measuring circuit. When the parameter is an S parameter, the measuring apparatus 108 is an S-parameter measuring circuit. The S-parameter measuring circuit is, for example, a network analyzer capable of measuring an S parameter from reflected waves, phase, and so on. The measuring apparatus 108 may be a portable apparatus.

The program of the embodiment is provided to the third information processing apparatus 21 in, for example, any of the following manners.
(1) Installed in the storage apparatus 103 in advance
(2) Provided by the removable storage medium 150
(3) Provided from a program server (not illustrated) via the communication interface 105

In addition, a portion of the third information processing apparatus 21 in accordance with the embodiment may be achieved by hardware. Alternatively, the third information processing apparatus 21 in accordance with the embodiment may be achieved by a combination of software and hardware.

Various methods may be used to change the lengths of the lot-management core wires 25 of the individual managed cables, instead of bending the lot-management core wires 25 backward. For each cable, a predetermined warp may be made in a lot management core wire 25 extending within the cable in parallel with an information transmission core wire 24, so that each cable includes a lot management core wire 25 having a different length.

As described above, in the embodiment, the parameter to be measured is made unique by adjusting the length of the lot management core wire 25, but components (ratio between the amounts of components) of the lot management core wire 25 maybe adjusted to achieve a unique parameter for each cable. In one possible example, impurities are added to a conductor included in the lot management core wire 25, and the impurity content is adjusted to make a measured parameter, e.g., an ohmic value, different for each cable. The measuring unit 28 measures, for example, unique ohmic values set by adjusting the impurity contents for individual managed cables, thereby obtaining a value specific to each of the plurality of managed cables. Using the parameter of the lot management core wire 25 and management information 30, the processing unit 27 identifies the lot information of the cable 23. In this way, adjusting the impurity content of a conductor included in the lot management core wire 25 achieves an effect similar to the effect achieved by bending the cable backward, and such a configuration may be defined as an example of the subject configuration. This is also true for embodiments 2-4, which will be described hereinafter.

Note that parameters of cables connected to an apparatus located within an environment (e.g., data center) where the third information processing apparatus 21 is set up may be collected from the apparatus over a network, and the lot information of cables connected to a plurality of information processing apparatuses may be managed in an integrated fashion.

### Embodiment 2

In an information processing system in accordance with embodiment 2, two information processing apparatuses connected to each other by a cable each measure a parameter of a lot management core wire of the cable and compare the results of measurement to inspect consistency between the measured parameters.

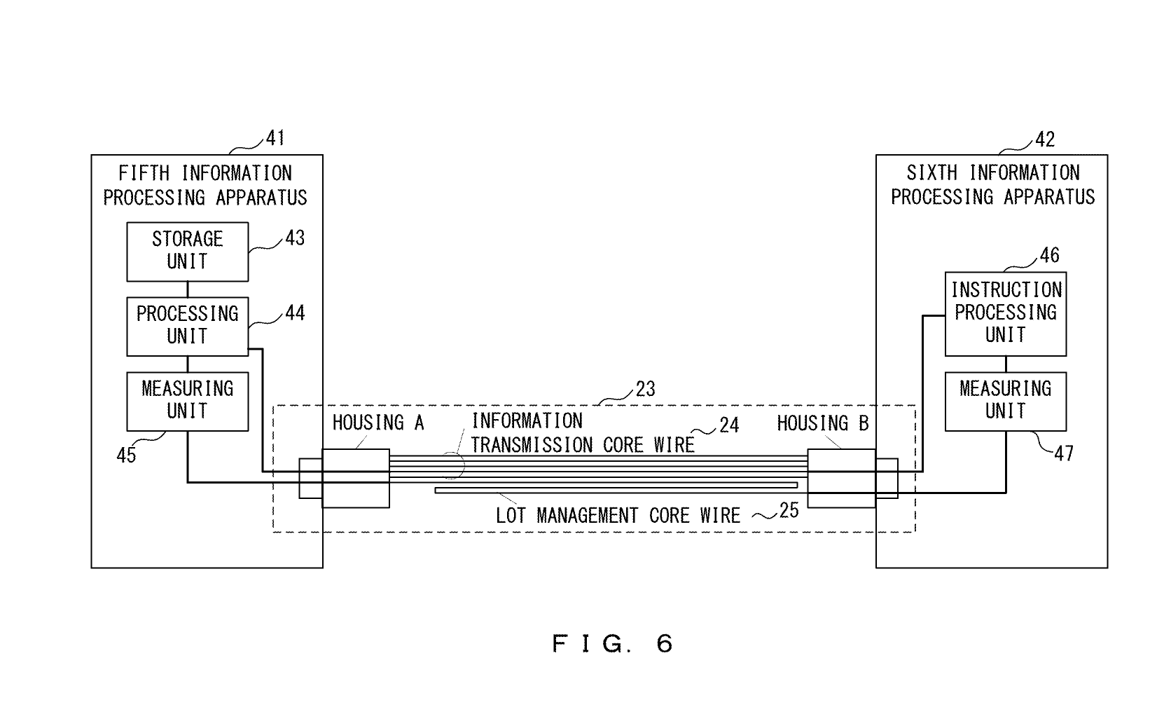

FIG. 6 illustrates an exemplary configuration of a cable-connected information processing system in accordance with embodiment 2. In FIG. 6, the information processing system includes a fifth information processing apparatus 41 and a sixth information processing apparatus 42. The fifth information processing apparatus 41 and the sixth information processing apparatus 42 are connected to each other by a cable 23. Note that the cable 23 in accordance with embodiment 2 is similar to the cable described with reference to embodiment 1.

The fifth information processing apparatus 41 is an example of the first information processing apparatus 2. The sixth information processing apparatus 42 is an example of the second information processing apparatus 3. The cable 23 is an example of the cable 1.

The fifth information processing apparatus 41 includes a storage unit 43, a processing unit 44, and a measuring unit 45.

The storage unit 43 stores management information 30. Management information 30 is similar to the management information 30 in embodiment 1.

The processing unit 44 obtains a parameter of the lot management core wire 25 measured by the sixth information processing apparatus 42 from the sixth information processing apparatus 42 via, for example, the information transmission core wire 24. The processing unit 44 instructs the measuring unit 45 to measure a parameter of the lot management core wire 25 and obtains the result of measurement from the measuring unit 45. The parameter measured by the fifth information processing apparatus 41 will hereinafter be referred to as a first parameter, and the parameter measured by the sixth information processing apparatus 42 will hereinafter be referred to as a second parameter. The processing unit 44 compares the first parameter obtained from the measuring unit with the second parameter obtained from the sixth information processing apparatus 42 so as to determine whether the first and second parameters are consistent with each other. When the first and second parameters are identical with each other, the processing unit 44 determines that the results of measurement of the parameters of the lot management core wire 25 are normal. When the first and second parameters are not identical with each other, the processing unit 44 determines that the results of measurement of the parameters are abnormal.

When the processing unit 44 determines that the results of measurement of the parameters are abnormal, the processing unit 44 performs an abnormality process. In an abnormality process, the processing unit 44 may measure the parameters again. That is, the processing unit 44 first instructs the sixth information processing apparatus 42 to measure the parameter of the lot management core wire 25 again, and obtains the measured second parameter from the sixth information processing apparatus 42. Then, the processing unit 44 instructs the measuring unit 45 to measure the first parameter again, and obtains the measured parameter from the measuring unit 45. The processing unit 44 compares the first and second parameters obtained from the remeasurement with each other so as to determine whether the results of remeasurement are normal.

In another abnormality process, a message indicating that the result of measurement is abnormal may be output to an output apparatus of the fifth information processing apparatus 41. The fact that the result of measurement is judged to be abnormal means, for example, that the lot management core wire 25 has a likelihood of being broken or shorted.

When the result of measurement of the parameters is judged to be normal, the processing unit 44 identifies lot information of the cable 23 using the identical parameters and management information 30. That is, the processing unit 44 extracts, from management information 30, a record whose value of parameter 32 indicates a value that is identical with the measured parameter, and obtains the value of lot information 31 of the extracted record. In this way, the processing unit 44 identifies lot information of the cable 23.

The measuring unit 45 receives from the processing unit 44 an instruction to measure the parameter of the lot management core wire 25 and measures the parameter of the lot management core wire 25. The measuring unit 45 transmits the measured parameter of the lot management core wire 25 to the processing unit 44. In one possible example, upon receiving from the processing unit 44 an instruction to measure the parameter again, the measuring unit 45 again measures and transmits the parameter of the lot management core wire 25 to the processing unit 44.

The sixth information processing apparatus 42 includes an instruction processing unit 46 and a measuring unit 47.

The instruction processing unit 46 instructs the measuring unit 47 to measure a second parameter of the lot management core wire 25, and receives the measured second parameter from the measuring unit 47. The instruction processing unit 46 transmits the received second parameter to the fifth information processing apparatus 41 via, for example, the information transmission core wire 24.

In one possible example, upon receiving from the fifth information processing apparatus 41 an instruction to measure the parameter again, the instruction processing unit 46 instructs the measuring unit 47 to measure the second parameter again, and receives the measured second parameter from the measuring unit 47. The instruction processing unit 46 may transmit the second parameter measured again to the fifth information processing apparatus 41.

The measuring unit 47 receives from the instruction processing unit 46 an instruction to measure the parameter of the lot management core wire 25, and measures the parameter of the lot management core wire 25. The measuring unit 47 transmits the measured parameter of the lot management core wire 25 to the instruction processing unit 46.

Note that the fifth information processing apparatus 41 may obtain the second parameter over a network connecting the fifth information processing apparatus 41 and the sixth information processing apparatus 42.

The hardware configurations of the fifth information processing apparatus 41 and the sixth information processing apparatus 42 are similar to that illustrated in FIG. 5.

In the fifth information processing apparatus 41, the CPU 101 depicted in FIG. 5 provides some or all of the functions of the processing unit 44. The storage apparatus 103 is an example of the storage unit 43. The measuring apparatus 108 is an example of the measuring unit 45.

In the sixth information processing apparatus 42, the CPU 101 depicted in FIG. 5 provides some or all of the functions of the instruction processing unit 46. The measuring apparatus 108 is an example of the measuring unit 47.

### Embodiment 3

A cable in accordance with embodiment 3 enables a parameter of a lot management core wire to be measured without using a pin of the cable.

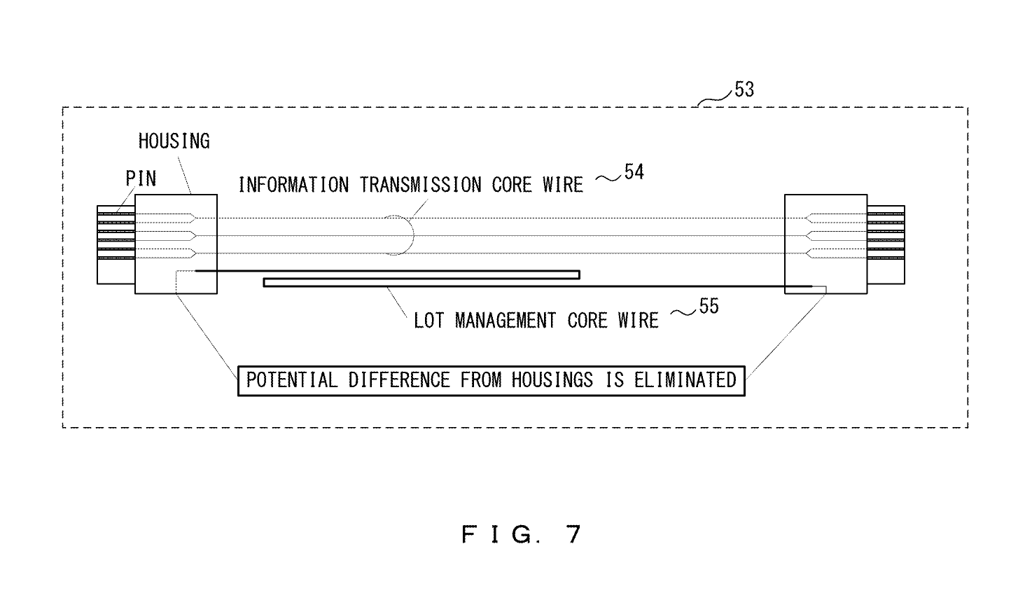

FIG. 7 illustrates an exemplary configuration of a cable in accordance with embodiment 3. In FIG. 7, a cable 53 includes an information transmission core wire 54 and a lot management core wire 55. The information transmission core wire 54 is similar to the information transmission core wire 24 of the cable 23 in embodiment 1.

As in the case of the cable 23 in embodiment 1, the lot management core wire is used to identify lot information of the cable 53. However, housings provided at the individual ends of the cable 53 are composed of a metal or conductive material. Thus, predetermined portions of the housings can be used to establish a connection between the lot management core wire 55 and an external element without using a pin. In terms of the other factors, the lot management core wire 55 is similar to the lot management core wire 25 of the cable 23 in embodiment 1.

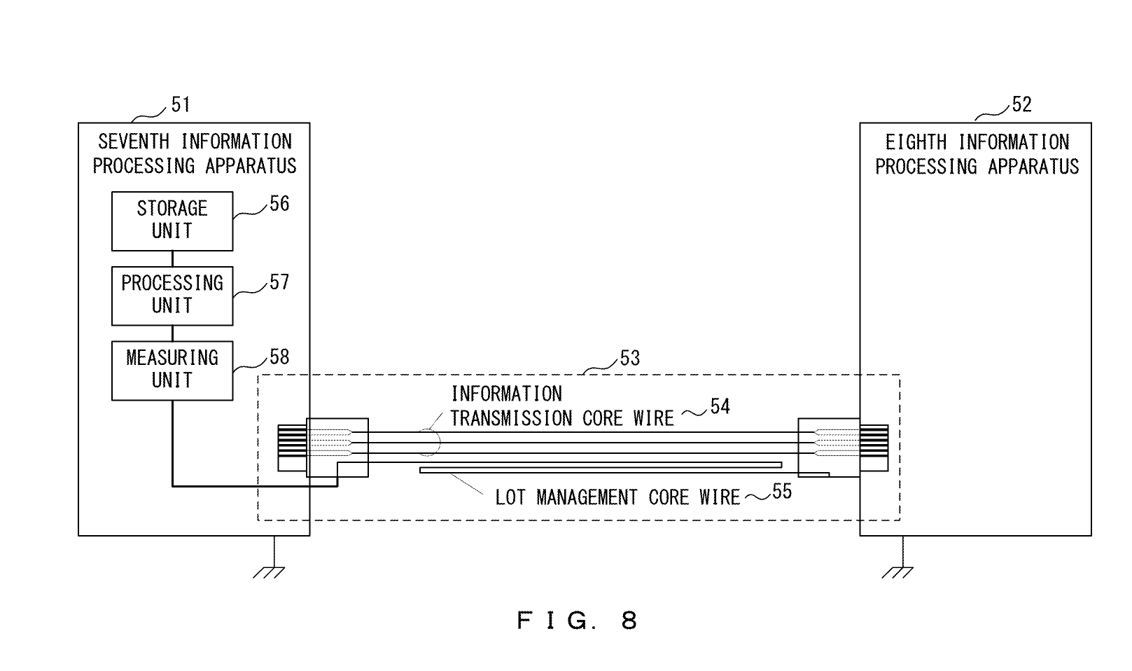

FIG. 8 illustrates an exemplary configuration of a cable-connected information processing system in accordance with embodiment 3. Referring to FIG. 8, the information processing system includes a seventh information processing apparatus 51 and an eighth information processing apparatus 52. A cable 53 connects the seventh information processing apparatus 51 and the eighth information processing apparatus 52. The eighth information processing apparatus 52 is similar to the fourth information processing apparatus 22 in embodiment 1.

The seventh information processing apparatus 51 is an example of the first information processing apparatus 2. The eighth information processing apparatus 52 is an example of the second information processing apparatus 3. The cable 53 is an example of the cable 1. The information transmission core wire 54 is an example of the first core wire 4. The lot management core wire 55 is an example of the second core wire 5.

The seventh information processing apparatus 51 includes a storage unit 56, a processing unit 57, and a measuring unit 58.

The storage unit 56 stores management information 30. Management information 30 is similar to the management information 30 of embodiment 1.

The processing unit 57 instructs a measuring unit 58 to measure the parameter of the lot management core wire 55 and receives the measured parameter from the measuring unit 58. In terms of factors other than the process of obtaining the parameter of the lot management core wire 55, the processing unit 57 is similar to the processing unit 27 in embodiment 1.

The measuring unit 58 receives from the processing unit 57 an instruction to measure the parameter of the lot management core wire 55, and measures the parameter of the lot management core wire 55 using, for example, a connector or plug connected to a predetermined portion of a housing rather than using a pin of the cable 53. In the case of measuring ohmic values as parameters, the measured parameters may include the ohmic value of the housing. The measuring unit 58 transmits the measured parameter of the lot management core wire 55 to the processing unit 57.

The cable 53 in embodiment 3 includes housings composed of a metal or conductive material and thus can be connected to an external element using a predetermined portion of the housings rather than using a pin. This may decrease the number of pins of the lot management core wire 55. Consequently, the process related to the production of pins corresponding to the lot management core wire 55 can be reduced in the process of assembling the cable 53, thereby decreasing the cost of fabrication of the cable.

The lot management core wire 55 may be used to eliminate a potential difference between the information processing apparatuses connected to the individual ends of the cable.

The hardware configuration of the fifth information processing apparatus is similar to the configuration depicted in FIG. 5. In the seventh information processing apparatus 51, the CPU 101 depicted in FIG. 5 provides some or all of the functions of the processing unit 57. The storage apparatus 103 is an example of the storage unit 56. The measuring apparatus 108 is an example of the measuring unit 58.

### Embodiment 4

An information processing apparatus of an information processing system in accordance with embodiment 4 receives lot information input by a user and outputs position information of a cable 23 corresponding to the input lot information, and the position information indicates a position located within the information processing system.

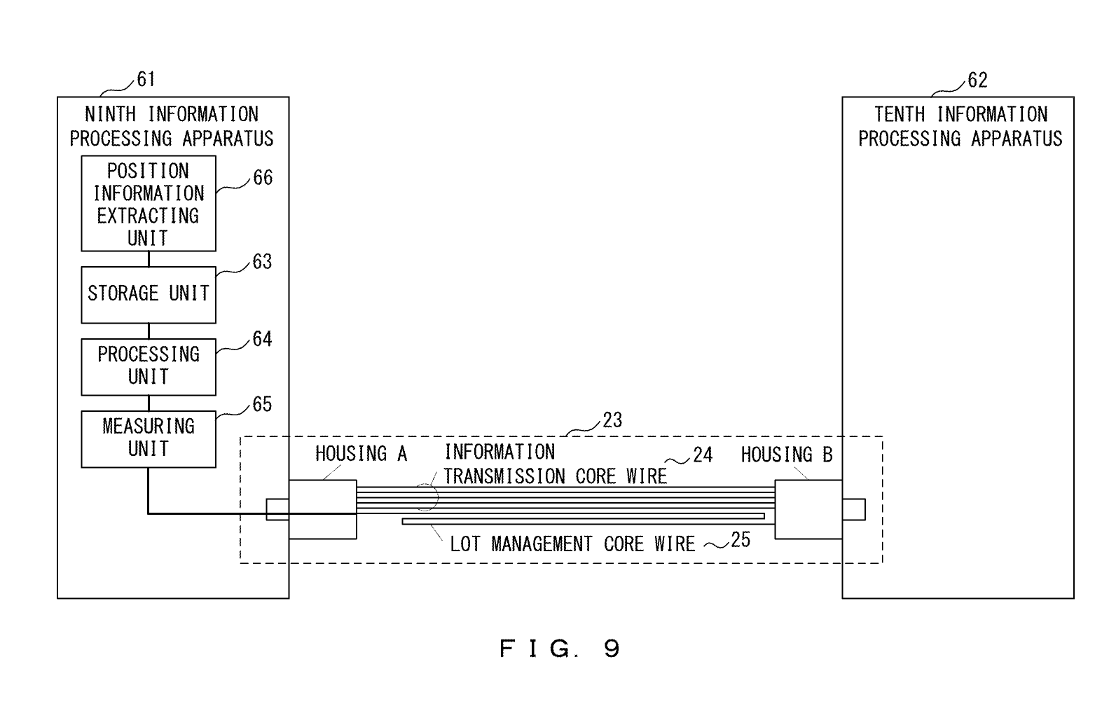

FIG. 9 illustrates an exemplary configuration of a cable-connected information processing system in accordance with embodiment 4. Referring to FIG. 9, the information processing system includes a ninth information processing apparatus 61 and a tenth information processing apparatus 62. A cable 23 connects the ninth information processing apparatus 61 and the tenth information processing apparatus 62. The cable 23 in embodiment 4 is similar to the cable described with reference to embodiment 1.

The ninth information processing apparatus 61 is an example of the first information processing apparatus 2. The tenth information processing apparatus 62 is an example of the second information processing apparatus 3. The cable 23 is an example of the cable 1.

The ninth information processing apparatus 61 includes a storage unit 63, a processing unit 64, a measuring unit 65, and a position information extracting unit 66.

The processing unit 64 instructs the measuring unit 65 to measure the parameter of the lot management core wire 25 and receives the measured parameter from the measuring unit 65. In addition, the processing unit 64 obtains position information of the cable 23. Position information of the cable 23 is information for determining where the cable 23 is connected within the information processing system. Position information includes, for example, identification information (e.g., host name) of the information processing apparatus and the device number or slot number of an input-output interface to which the cable 23 is connected. Position information of the cable 23 may be obtained in response to, for example, a command from an OS (Operating System) operated in the ninth information processing apparatus 61.

Subsequently, as in the case of embodiment 1, the processing unit 64 identifies lot information of the cable 23 using the measured parameter and management information 30, which is stored in the storage unit 63. The processing unit 64 associates and stores the identified lot information and the obtained position information in the storage unit 63 as position management information.

The storage unit 63 stores management information and position management information. Management information 30 is similar to the management information 30 in embodiment 1. Position management information includes lot information and position information associated therewith.

The measuring unit 65 receives an instruction to measure the parameter of the lot management core wire 25 from the processing unit 64, and measures the parameter of the lot management core wire 25. The measuring unit 65 transmits the measured parameter of the lot management core wire 25 to the processing unit 64.

The position information extracting unit 66 receives lot information input by the user using a predetermined input apparatus. Then, the position information extracting unit 66 obtains position information associated with the input lot information from position management information. The position information extracting unit 66 outputs the obtained position information to a predetermined output apparatus.

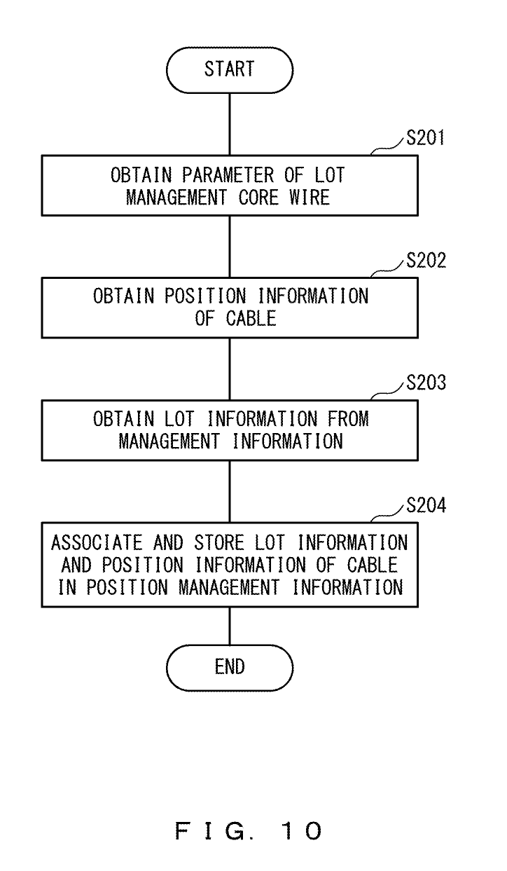

FIG. 10 is a flowchart illustrating processes performed by the processing unit 64 of the ninth information processing apparatus 61 in accordance with embodiment 4.

Referring to FIG. 10, the processing unit 64 instructs the measuring unit 65 to measure the parameter of the lot management core wire 25 and obtains the measured parameter from the measuring unit 65 (S201). The processing unit 64 obtains position information of the cable 23 (S202). The processing unit 64 obtains lot information using the measured parameter and management information 30 (S203). The processing unit 64 associates and stores the lot information obtained in S203 and the position information obtained in S202 in the storage unit 63 as position management information (S204). Then, the flow ends.

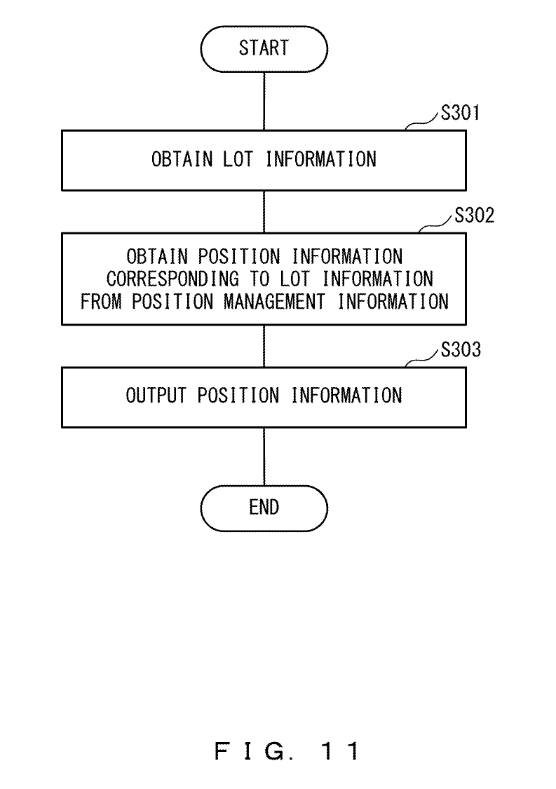

FIG. 11 is a flowchart illustrating processes performed by the position information extracting unit 66 of the ninth information processing apparatus 61 in accordance with embodiment 4.

Referring to FIG. 11, the position information extracting unit 66 receives lot information input by the user (S301). The position information extracting unit 66 obtains position information corresponding to the lot information input in S301 from position management information (S302). The position information extracting unit 66 outputs the position information extracted in S302 to a predetermined output apparatus (S303). Then, the flow ends.

The following will describe the hardware configuration of the ninth information processing apparatus 61. The hardware configuration of the ninth information processing apparatus 61 is similar to that depicted in FIG. 5.

In the ninth information processing apparatus 61, the CPU 101 depicted in FIG. 5 provides some or all of the functions of the processing unit 64 and the position information extracting unit 66. The position information extracting unit 66 receives lot information input by the user using an input apparatus and transmitted via the input interface 106. The position information extracting unit 66 outputs the obtained position information to an output apparatus via the output interface 107. The storage apparatus 103 is an example of the storage unit 63. The measuring apparatus 108 is an example of the measuring unit 65.

In response to, for example, a command input by the user, the processing unit 64 may start to give an instruction to measure the parameter of the lot management core wire 25 and to obtain position information. When the cable 23 is unplugged from or inserted into the ninth information processing apparatus 61, the parameter may be measured again and stored in management information 30.

The lot management core wire 25 may be used to eliminate a potential difference between the information processing apparatuses connected to the individual ends of the cable.

An embodiment is not limited to those described above, and various configurations or embodiments maybe used without departing from the spirit of the embodiment.

An aspect may provide a cable that can be identified after this cable is laid. The information processing system in accordance with the embodiment enables a system administrator to identify where in the information processing system a communication cable having predetermined lot information is used, without managing additional information that would be recorded during the process of laying the cable.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing system comprising:
a cable configured to connect information processing apparatuses to each other, the cable including one or more first core wires through which information is transmitted, and one or more second core wires having a shape or component associated with preset information; and
a first information processing apparatus configured to measure a first parameter that is related to the second core wires and changes with the shape or component, and to identify the cable using the measured first parameter.

2. The information processing system according to claim 1, wherein
the shape is a length or bending pattern of the second core wires.

3. The information processing system according to claim 1, wherein
the second core wires are bent backward in a pattern associated with lot information of the cable.

4. The information processing system according to claim 1, further comprising:
a second information processing apparatus connected to the first information processing apparatus via the cable, wherein
the second information processing apparatus measures a second parameter that is related to the second core wires and that changes with the shape or component, and transmits the measured second parameter to the first information processing apparatus, and
the first information processing apparatus determines whether the first and second parameters are consistent with each other.

5. The information processing system according to claim 1, wherein
the first parameter is an ohmic value, an S parameter, or a measured value based on time domain reflectometry.

6. The information processing system according to claim 1, wherein
the cable includes a housing of conductive material connected to the second core wires, and
the first information processing apparatus measures the first parameter via the housing.

7. An information processing apparatus comprising:
a measuring unit configured to measure a first parameter that is related to one or more second core wires having a shape or component associated with preset information and that changes with a shape or component of the second core wires, the second core wires being included in a cable that connects the information processing apparatus and another information processing apparatus to each other and further includes one or more first core wires through which information is transmitted; and
an identifying unit configured to identify the cable using the measured first parameter.

8. The information processing apparatus according to claim 7, wherein
the shape is a length or bending pattern of the second core wires.

9. The information processing system according to claim 7, wherein
the second core wires are bent backward in a pattern associated with lot information of the cable.

10. The information processing apparatus according to claim 7, wherein
the specifying unit receives, from the another information processing apparatus connected via the cable, a second parameter measured by the another information processing apparatus, and determines whether the second parameter is consistent with the first parameter, the second parameter being related to the second core wires and changing with the shape or component.

11. The information processing apparatus according to claim 7, wherein
the first parameter is an ohmic value, an S parameter, or a measured value based on time domain reflectometry.

12. The information processing apparatus according to claim 7, wherein
the cable includes a housing of conductive material connected to the second core wires, and
the measuring unit measures the first parameter via the housing.

13. A cable comprising:
one or more first core wires through which information is transmitted; and
one or more second core wires having a shape or component associated with preset information.

14. The cable according to claim 13, wherein
the shape is a length or bending pattern of the second core wires.
